(19) United States
(12) Patent Application Publication
(10) Pub. No.: US 2016/0135291 A1
(43) Pub. Date: May 12, 2016

(54) PRINTED CIRCUIT BOARD STRUCTURE

(71) Applicants: Hsin-Ting Liu, New Taipei City (TW); Ming-Jen Lin, New Taipei City (TW); Chun-Hung Chen, New Taipei City (TW)

(72) Inventors: Hsin-Ting Liu, New Taipei City (TW); Ming-Jen Lin, New Taipei City (TW); Chun-Hung Chen, New Taipei City (TW)

(73) Assignee: ASMEDIA TECHNOLOGY INC., New Taipei City (TW)

(21) Appl. No.: 14/932,944

(22) Filed: Nov. 4, 2015

(30) Foreign Application Priority Data
Nov. 11, 2014 (TW) 103139060

(51) Int. Cl. H05K 1/02; H05K 1/11

(52) U.S. Cl. CPC H05K 1/0298; H05K 1/117; H05K 2201/093; H05K 2201/094; H05K 2201/09345

(57) ABSTRACT

A printed circuit board structure includes a main body and a connecting interface. The connecting interface connects and is located at a side of the main body. The connecting interface includes conductive layers and insulation layers. The conductive layers at least include a first, a second, a third, a fourth conductive layer. The insulation layers at least include a first, a second, a third insulation layers. The insulation layers and the conductive layers are alternately disposed. The first insulation layer is located between the first conductive layer and the second conductive layer. The first conductive layer and the second conductive layer are partially overlapped in their orthographic projections on the first insulation layer. The second insulation layer is located between the second conductive layer and the third conductive layer. The third insulation layer is located between the third conductive layer and the fourth conductive layer.

### CROSS-REFERENCE TO RELATED APPLICATION

This application claims the priority benefit of TW application serial No. 103139060, filed on Nov. 11, 2014. The entirety of the above-mentioned patent applications is hereby incorporated by reference herein and made a part of specification.

### BACKGROUND OF THE INVENTION

1. Field of the Invention

The disclosure relates to a circuit board structure and, more particularly, to a printed circuit board structure.

2. Description of the Related Art

With technology development, computing functions and information transmission efficiency of components of an electronic device are increased. For a large amount of information transmission, connectors having high speed data transmission efficiency are disposed in the electronic device.

Generally, a plurality of connecting pads are disposed on a printed circuit board to correspond to connection terminals of the connector subsequently disposed on the printed circuit board for electrically connecting to the connectors of the electronic device. The connectors of the electronic device are matched with the connectors disposed on the printed circuit board to transmit data. However, the entire thickness of the printed circuit board is increased to causes the size problem in the electronic device.

### BRIEF SUMMARY OF THE INVENTION

The printed circuit board structure includes a main body and a connecting interface connected to the main body and located at a side of the main body. The connecting interface includes a plurality of conductive layers and a plurality of insulation layers. The insulation layers and the conductive layers are alternately disposed. The conductive layers at least include a first conductive layer, a second conductive layer, a third conductive layer and a fourth conductive layer. The insulation layers at least include a first insulation layer, a second insulation layer and a third insulation layer. The first insulation layer is located between the first conductive layer and the second conductive layer. An orthographic projection of the first conductive layer on the first insulation layer is partially overlapped with an orthographic projection of the second conductive layer on the first insulation layer. The second insulation layer is located between the second conductive layer and the third conductive layer. The third insulation layer is located between the third conductive layer and the fourth conductive layer.

### BRIEF DESCRIPTION OF THE DRAWINGS

These and other features, aspects and advantages of the disclosure will become better understood with regard to the following embodiments and accompanying drawings.

FIG. 1 is a top view showing a printed circuit board structure in an embodiment;

FIG. 2 is a top view showing a first conductive layer and a fourth conductive layer of a connecting interface of the printed circuit board structure in FIG. 1;

FIG. 3 is a sectioned view showing part of the connecting interface of the printed circuit board structure in FIG. 1;

FIG. 4 is an exploded view showing part of the connecting interface of the printed circuit board structure in FIG. 1.

### DETAILED DESCRIPTION OF THE EMBODIMENTS

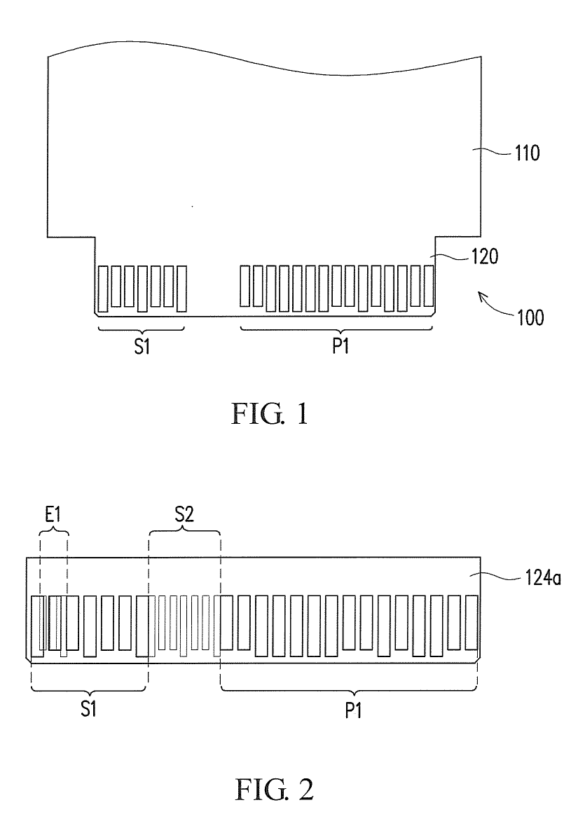

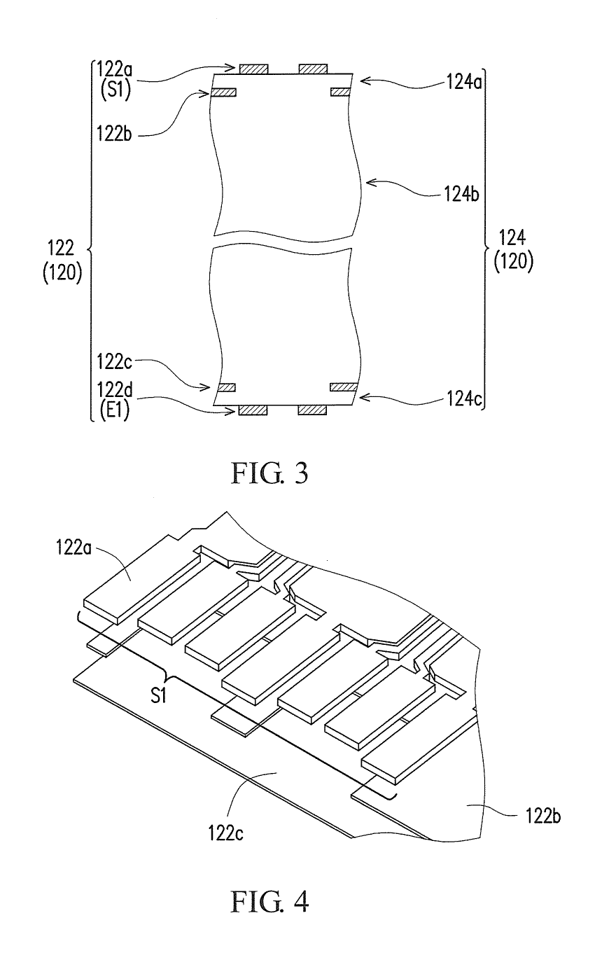

FIG. 1 is a top view showing a printed circuit board structure in an embodiment. FIG. 2 is a top view showing a first conductive layer and a fourth conductive layer of a connecting interface of the printed circuit board structure in FIG. 1. FIG. 3 is a sectioned view showing part of the connecting interface of the printed circuit board structure in FIG. 1. FIG. 4 is an exploded view showing part of the connecting interface of the printed circuit board structure in FIG. 1. FIG. 3 and FIG. 4 are sectioned views only showing the position of a high speed signal terminals S1 in FIG. 2.

Please refer to FIG. 1, FIG. 3 and FIG. 4. In the embodiment, a printed circuit board structure 100 includes a main body 110 and a connecting interface 120. The connecting interface 120 is connected to the main body 110 is located at a side of the main body 110. The connecting interface 120 includes a plurality of conductive layers 122 and a plurality of the insulation layers 124. In an embodiment, the conductive layers 122 at least include a first conductive layer 122a, a second conductive layer 122b, a third conductive layer 122c and a fourth conductive layer 122d. The insulation layers 124 and the conductive layers 122 are alternately disposed, and the insulation layers 124 at least include a first insulation layer 124a, a second insulation layer 124b and a third insulation layer 124c.

Please refer to FIG. 3 and FIG. 4. The first insulation layer 124a is located between the first conductive layer 122a and the second conductive layer 122b. An orthographic projection of the first conductive layer 122a on the first insulation layer 124a is partially overlapped with an orthographic projection of the second conductive layer 122b on the first insulation layer 124a. The second insulation layer 124b is located between the second conductive layer 122b and the third conductive layer 122c. The third insulation layer 124c is located between the third conductive layer 122c and the fourth conductive layer 122d. As shown in FIG. 3, the second conductive layer 122b and the third conductive layer 122c are located between the first conductive layer 122a and the fourth conductive layer 122d, and the second insulation layer 124b is located between the first insulation layer 124a and the third insulation layer 124c.

In detail, in the embodiment, the thickness of the main body 110 and the thickness of the connecting interface 120 are the same, and the main body 110 is connected to the connecting interface 120 seamlessly, or they are integrated formed. Preferably, in the embodiment, the thickness of the connecting interface 120 is between 0.8 mm and 1.6 mm, and the thickness of the main body 110 is also between 0.8 mm and 1.6 mm correspondingly. In the embodiment, the connecting interface 120 is such as a serial advanced technology attachment (SATA) express interface portion, the first conductive layer 122a is formed by seven high speed signal terminals S1 and fifteen power supply terminals P1, and the fourth conductive layer 122d is formed by three signal terminals E1 and seven high speed signal terminals S2. The high speed signal terminal S1, S2 is the signal terminals whose transmission speed is above 1 Gbps, and the transmission speed of the signal terminal E1 is below 1 Gbps.

Further, as shown in FIG. 2, FIG. 3 and FIG. 4, the high speed signal terminal S1 is partially overlapped with the second conductive layer 122b, and the power supply terminal P1 is entirely overlapped with the second conductive layer 122b. As shown in FIG. 2 and FIG. 3, the orthographic projection of the first conductive layer 122a on the first insulation layer 124a is partially overlapped with the orthographic projection of the fourth conductive layer 122d on the first insulation layer 124a. The high speed signal terminals S1, S2, the signal terminal E1 and the power supply terminal P1 are directly disposed on the printed circuit board structure 100 by the copper foil corrosion method. As a result, in the embodiment, the connecting pads on the printed circuit board and the corresponding SATA express connector are not needed for the specification of the SATA express. Therefore, in the embodiment, the printed circuit board structure 100 is small and thin. In addition, since the printed circuit board structure 100 includes the main body 110 and the connecting interface 120, the printed circuit board structure 100 both includes a function of the connector (that is, the connecting interface 120 is directly coupled to the external electronic components) and a function of the circuit board (that is, the main body 110 can transmit signals).

Additionally, in the embodiment, the orthographic projection of the second conductive layer 122b on the second insulation layer 124b is overlapped with the orthographic projection of the third conductive layer 122c on the second insulation layer 124b. The second conductive layer 122b is such as a ground plane, or a power plane, or a ground plane and a power plane, and the third conductive layer 122c is such as a ground plane, or a power plane, or a ground plane and a power plane. In detail, the second conductive layer 122b is used to decrease an induction area of the first conductive layer 122a, so as to increase the resistance and the characteristic impedance, and then to achieve the impedance matching. Similarly, the third conductive layer 122c is also used to decrease an induction area of the fourth conductive layer 122d, so as to increase the resistance and the characteristic impedance, and then to achieve the impedance matching.

The number of layers of the conductive layers 122 and the number of the insulation layers 124 of the connecting interface 120 is not limited to above embodiments. Although in the above embodiments, the conductive layers 122 includes four layers, the insulation layers 124 includes three layers, in another embodiments not shown, the conductive layers 122 includes an even number of layers, such as six layers, eight layers, ten layers, and the insulation layers 124 includes an odd number of layers, such as five layers, seven layers, nine layers. In an embodiment, only if the thickness of the connecting interface 120 is between 0.8 mm and 1.6 mm, the number of layers is not limited herein.

Since the printed circuit board structure includes the main body and the connecting interface, and the orthographic projection of the first conductive layer of the connecting interface on the first insulation layer is partially overlapped with the orthographic projection of the second conductive layer on the first insulation layer, the printed circuit board structure both include a function of the connector (coupled to the external electronic components) and a function of the circuit board (signal transmission). Furthermore, the printed circuit board structure is small and thin, the preferable impedance matching is achieved, and the impedance discontinuity is avoided.

What is claimed is:

1. A printed circuit board structure, comprising:
a main body; and
a connecting interface connected to the main body and located at a side of the main body, wherein the connecting interface includes:
a plurality of conductive layers; and
a plurality of insulation layers, wherein the insulation layers and the conductive layers are alternately disposed,
wherein a first insulation layer of the insulation layers is located between a first conductive layer and a second conductive layer of the conductive layers, an orthographic projection of the first conductive layer on the first insulation layer is partially overlapped with an orthographic projection of the second conductive layer on the first insulation layer, a second insulation layer of the insulation layers is located between the second conductive layer and a third conductive layer of the conductive layers, a third insulation layer of the insulation layers is located between the third conductive layer and a fourth conductive layer of the conductive layers.

2. The printed circuit board structure according to claim 1, wherein a thickness of the main body is the same with that of the connecting interface.

3. The printed circuit board structure according to claim 2, wherein the thickness of the connecting interface is between 0.8 mm to 1.6 mm.

4. The printed circuit board structure according to claim 1, wherein the connecting interface is a serial advanced technology attachment express interface portion.

5. The printed circuit board structure according to claim 4, wherein the first conductive layer includes 7 high speed signal terminals and 15 power supply terminals, the high speed signal terminals are partially overlapped with the second conductive layer, and the power supply terminals are overlapped with the second conductive layer.

6. The printed circuit board structure according to claim 4, wherein the fourth conductive layer includes 3 signal terminals and 7 high speed signal terminals.

7. The printed circuit board structure according to claim 4, wherein an orthographic projection of the first conductive layer on the first insulation layer is partially overlapped with an orthographic projection of the fourth conductive layer on the first insulation layer.

8. The printed circuit board structure according to claim 1, wherein an orthographic projection of the second conductive layer on the second insulation layer is overlapped with an orthographic projection of the third conductive layer on the second insulation layer.

9. The printed circuit board structure according to claim 1, wherein the second conductive layer includes a ground plane, or a power plane, or both the ground plane and the power plane.

10. The printed circuit board structure according to claim 1, wherein the third conductive layer includes a ground plane, or a power plane, or both the ground plane and the power plane.
